(19) United States
(12) Patent Application Publication
(10) Pub. No.: US 2026/0040859 A1
(43) Pub. Date: Feb. 5, 2026

(54) GAS DISTRIBUTION ASSEMBLY AND SUBSTRATE PROCESSING DEVICE

(71) Applicant: SwaySure Technology Ca., Ltd., Shenzhen (CN)

(72) Inventor: Takayuki FUKASAWA, Shenzhen (CN)

(21) Appl. No.: 19/256,357

(22) Filed: Jul. 1, 2025

(30) Foreign Application Priority Data
Aug. 1, 2024 (CN) 202411053457.9

(51) Int. Cl. H01L 21/67

(52) U.S. Cl. CPC H01L 21/67017

(57) ABSTRACT

A gas distribution assembly applied for a substrate processing device that includes a substrate seat and a reaction chamber. The reaction chamber is configured to accommodate a substrate, the substrate seat is configured to support the substrate, and the gas distribution assembly is configured to distribute gas to the surface of the substrate. The gas distribution assembly includes at least one output module, which further includes a gas chamber, at least one gas inlet, and a pulse valve located between the gas chamber and the at least one gas inlet. The gas chamber is connected to the at least one gas inlet, and the pulse valve corresponds one-to-one with the gas inlet and is located at an end of the gas inlet connected to the gas chamber.

### CROSS-REFERENCE TO RELATED APPLICATIONS

This application claims priority to Chinese Patent Application No. 202411053457.9, filed on Aug. 1, 2024, the entire disclosure of which is hereby incorporated herein by reference.

### TECHNICAL FIELD

The present application relates to the technical field of semiconductor manufacturing equipment, and particularly to a gas distribution assembly and a substrate processing device.

### BACKGROUND

The substrate processing device includes a gas distribution assembly, a reaction chamber, and a substrate seat. Substrates include wafers for fabricating semiconductor chips, substrate panels for manufacturing display panels, etc. Substrate processing includes dry etching, thin film deposition, dry cleaning, etc. Thin film deposition includes Chemical Vapor Deposition (CVD), Physical Vapor Deposition (PVD), and Atomic Layer Deposition (ALD).

During operation of the substrate processing device, a substrate is supported on the substrate seat 10, the reaction chamber 20 accommodates the substrate, and the gas distribution assembly 30 is connected to a gas source 40 to introduce gases into the reaction chamber 20 for performing the aforementioned substrate processing. Referring to FIG. 1, the substrate processing device is used for ALD film deposition, the gas distribution assembly 30 includes a showerhead 31 connected to the gas source 40 via a pipeline, and a control valve 32 is provided on the pipeline to control the gas source 40 to be in communication with the showerhead 31. In existing substrate processing devices, different types of gases (e.g., a first gas and a second gas) need to be alternately introduced into the reaction chamber 20. Since the control valve 32 is located on the pipeline, residual gases in the portion of the pipeline downstream of the control valve 32 and in the showerhead 31 must be discharged before switching gases, which results in a large volume of gas to be discharged and easily leaving residue, leading to mixing of the gases sequentially introduced within one cycle T, as shown in FIG. 2. When the mixed first and second gases chemically react in the gaseous state, the reaction products deposit on the surface of the substrate, reducing the uniformity of the ALD film.

### SUMMARY

There are provided a gas distribution assembly and a substrate processing device according to embodiments of the present application. The technical solution is as below:

According to a first aspect of embodiments of the present application, there is provided a gas distribution assembly, applied for a substrate processing device, the substrate processing device comprising a substrate seat and a reaction chamber, the reaction chamber being configured to accommodate a substrate, the substrate seat being configured to support the substrate, the gas distribution assembly being configured to distribute gas to a surface of the substrate;
the gas distribution assembly includes:
at least one output module comprising a gas chamber, at least one gas inlet, and a pulse valve located between the gas chamber and the gas inlet, wherein the gas chamber is connected to the at least one gas inlet, the pulse valve corresponds one-to-one with the gas inlet and is located at an end of the gas inlet connected to the gas chamber, and when the gas distribution assembly comprises a plurality of gas inlets, the plurality of gas inlets are distributed in a planar or curved manner;
the distributing gas to the surface of the substrate includes:
when the pulse valve is opened, gas in the gas chamber is delivered to the reaction chamber via the gas inlet.

According to a second aspect of embodiments of the present application, there is provided a substrate processing device, including: a reaction chamber configured to accommodate a substrate; a substrate seat configured to support the substrate, and the gas distribution assembly configured to distribute gas to a surface of the substrate.

It should be understood that the foregoing general description and the following detailed description are merely exemplary and explanatory, and are not intended to limit the present disclosure.

### BRIEF DESCRIPTION OF THE DRAWINGS

The accompanying drawings here are incorporated into the specification and constitute a part of the specification, and illustrate the embodiments conforming to the present application and, together with the specification, are used to explain the principles of the present application. Obviously, the drawings described below are merely some embodiments of the present application. For those skilled in the art, other drawings can also be obtained according to these drawings without creative efforts.

FIG. 1 is a schematic structural diagram of an existing substrate processing device.

FIG. 2 is a schematic diagram of the states of the first gas and the second gas in an existing reaction chamber.

FIG. 3 is a schematic structural diagram of the gas distribution assembly in an embodiment of the present application.

FIG. 4 is a schematic diagram of the connection between multiple gas inlets and the gas chamber in an embodiment of the present application.

FIG. 5 is a schematic structural diagram of the substrate processing device in an embodiment of the present application.

FIG. 6 is a schematic diagram of the states of the first gas and the second gas in the reaction chamber in an embodiment of the present application.

FIG. 7A is a schematic diagram of the pulse valve in the closed state in an embodiment of the present application.

FIG. 7B is a schematic diagram of the pulse valve in the open state in an embodiment of the present application.

FIG. 8A is a schematic diagram of a horizontally placed plasma generator in an embodiment of the present application.

FIG. 8B is a schematic diagram of a vertically placed plasma generator in an embodiment of the present application.

FIG. 9 is a schematic diagram of the gas chamber with an evaporation cavity in an embodiment of the present application.

FIG. 10A is a schematic diagram of the substrate processing device with a planar showerhead in an embodiment of the present application.

FIG. 10B is a schematic diagram of the substrate processing device with a convex showerhead in an embodiment of the present application.

FIG. 10C is a schematic diagram of the substrate processing device with a concave showerhead in an embodiment of the present application.

FIG. 11 is a schematic diagram of a batch substrate processing device in an embodiment of the present application.

FIG. 12 is an expanded schematic diagram of the cross-section A-A in FIG. 11.

### DETAILED DESCRIPTION OF THE EMBODIMENTS

Now, the exemplary embodiments will be described more comprehensively with reference to the accompanying drawings. However, the exemplary embodiments can be implemented in various forms and should not be construed as being limited to the examples set forth herein; rather, these embodiments are provided so that this application will be more thorough and complete, and the concept of the exemplary embodiments will be fully conveyed to those skilled in the art.

Furthermore, the described features, structures, or characteristics can be combined in any suitable manner in one or more embodiments. In the following description, numerous specific details are provided to give a thorough understanding of the embodiments of the present application. However, those skilled in the art will appreciate that the technical solutions of the present application can be practiced without one or more of the specific details, or other methods, components, devices, steps, etc. can be adopted. In other cases, well-known methods, devices, implementations, or operations are not shown or described in detail to avoid obscuring various aspects of the present application.

The present application will be further described in detail below in conjunction with the accompanying drawings and specific embodiments. It should be noted that the technical features involved in the various embodiments of the present application can be combined with each other as long as there is no conflict between them. The embodiments described below with reference to the accompanying drawings are exemplary and intended to explain the present application, and should not be construed as a limitation to the present application.

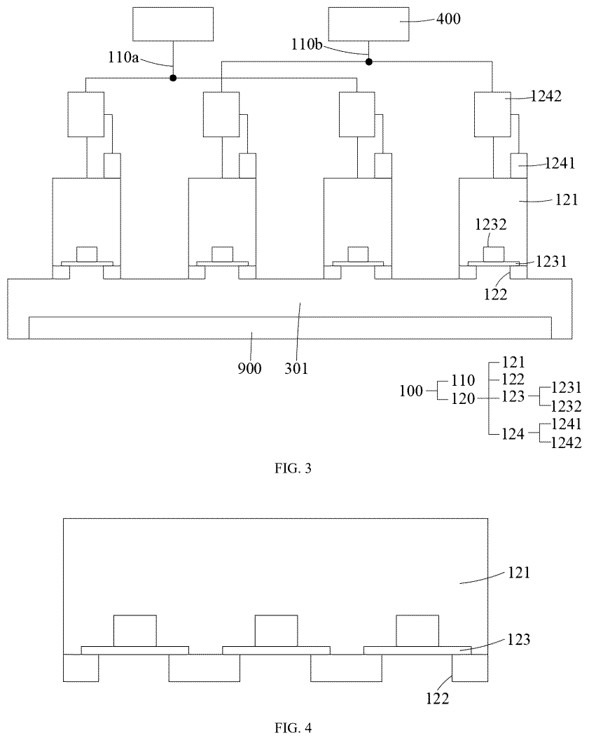

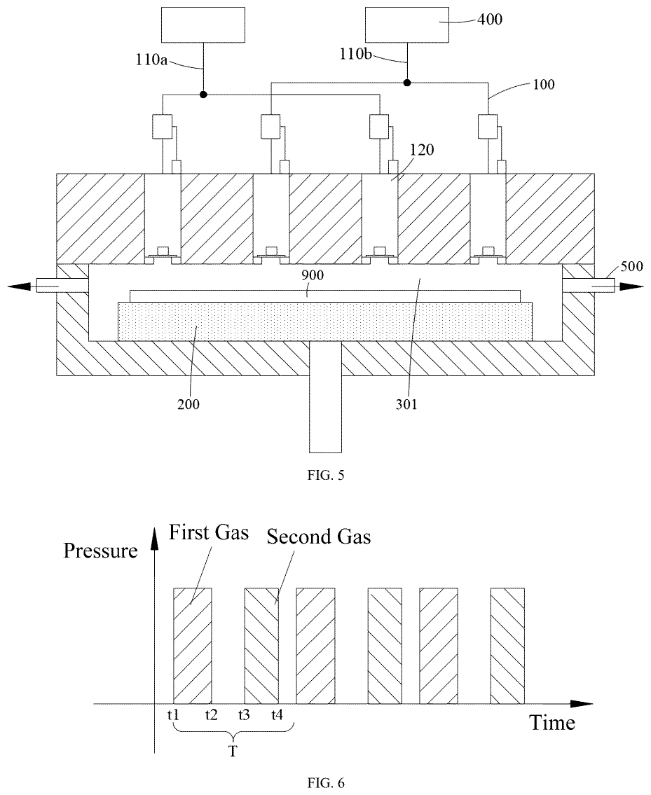

Referring to FIGS. 3 and 4, an embodiment of the present application provides a gas distribution assembly 100. Referring to FIG. 5, the gas distribution assembly 100 is used in a substrate processing device. The substrate processing device includes a substrate seat 200 and a reaction chamber 301. The reaction chamber 301 is used to accommodate a substrate 900, and the substrate seat 200 is at least partially located in the reaction chamber 301. The substrate seat 200 is used to support the substrate 900, and the gas distribution assembly 100 is used to distribute gas to the surface of the substrate 900. The gas distribution assembly 100 is connected to a gas source device 400, and the gas raw material in the gas source device 400 is transmitted to the surface of the substrate 900 exposed in the reaction chamber 301 through the gas distribution assembly 100. The substrate processing device further includes an exhaust device 500, and the exhaust device 500 is connected to the reaction chamber 301 for exhausting the gas in the reaction chamber 301.

Exemplarily, the substrate processing device is used for processes such as ALD and evaporation, but is not limited thereto, depending on the specific situation.

Exemplarily, the substrate 900 is a single crystal silicon wafer, but is not limited thereto. The substrate 900 can also be any substrate known to those skilled in the art for carrying semiconductor integrated circuits, which is not limited in the present application. Exemplarily, the substrate 900 may include semiconductor materials, for example, at least one of materials such as silicon (e.g., single crystal silicon Si), silicon germanium (SiGe), germanium (Ge), gallium arsenide (GaAs), indium phosphide (InP), and silicon carbide (SiC). In some embodiments, the substrate 900 can be a single-layer structure. For example, it can be a single-layer structure made of at least one of materials such as silicon, germanium, and gallium arsenide, but is not limited thereto. The substrate 900 can also be a multi-layer structure, for example, a composite substrate such as a stack including silicon and silicon germanium, a stack of silicon and silicon carbide, silicon on insulator, germanium on insulator, or silicon germanium on insulator. In other embodiments, the substrate 900 can also be an insulating substrate. The insulating substrate can be made of a non-conductive material such as glass, plastic, or a sapphire wafer, or the substrate 900 can also be an insulating dielectric material such as silicon dioxide (SiO₂) and silicon nitride (SiN).

The present application does not specifically limit the type of gas distributed by the gas distribution assembly 100 to the surface of the substrate 900. Exemplarily, the gas distribution assembly 100 can be connected to a gas source device 400 for providing gas raw materials. The gas raw materials can be process gases or purge gases. The gas source device 400 includes, for example, a gas storage device or a gas preparation device. The gas raw materials can also be at least partially ionized gases, that is, the gas source device 400 can also be a Remote Plasma Source (RMS), and the gas raw materials can include plasma, but are not limited thereto, depending on the specific situation.

In addition, the gas raw materials can be directly distributed by the gas distribution assembly 100, but are not limited thereto. They can also be distributed after being heated, cooled, or mixed in the gas distribution assembly 100, and can also be distributed after being ionized into plasma (which will be described in subsequent embodiments), depending on the specific situation.

As shown in FIGS. 3 to 5, the gas distribution assembly 100 includes at least one output module 120. The output module 120 includes a gas chamber 121, at least one gas inlet 122, and a pulse valve 123 located between the gas chamber 121 and the gas inlet 122. The gas chamber 121 is connected to at least one gas inlet 122. The pulse valves 123 correspond one-to-one with the gas inlets 122 and each pulse valve 123 is located at the end of each gas inlet 122 connected to the gas chamber 121. The gas inlets 122 are distributed in a planar or curved manner. Distributing process gas to the surface of the substrate 900 includes that when the pulse valve 123 is opened, the process gas in the gas chamber 121 is delivered to the reaction chamber 301 from the gas inlet 122.

Generally, the gas distribution assembly 100 further includes an input module 110. The input module 110 is used to connect to the gas source device 400. The output module 120 is in communication with the corresponding connected input module 110. The connection between the input module 110 and the output module 120 includes that the input module 110 is connected to the gas chamber 121. As shown in FIG. 3, one input module 110 can be connected to at least one output module 120. It can be understood that one output module 120 is connected to one input module 110. Thus, the gas raw material in the gas source device 400 is transmitted from the input module 110 to the corresponding connected output module 120 and then to the surface of the substrate 900 exposed in the reaction chamber 301.

In the embodiment shown in FIG. 3, the gas distribution assembly 100 includes a plurality of input modules 110, and one input module 110 is connected to a plurality of output modules 120, but it is not limited thereto. In some embodiments, the gas distribution assembly 100 includes one input module 110, and one or more output modules 120 are connected to the same input module 110. In some embodiments, the input modules 110 and the output modules 120 are connected in a one-to-one correspondence. In some embodiments, the number of output modules 120 connected to each input module 110 can be the same or different, depending on the specific situation.

The output module 120 includes a gas chamber 121, at least one gas inlet 122, and a pulse valve 123 located between the gas chamber 121 and the gas inlet 122. The gas chamber 121 is connected to at least one gas inlet 122. The pulse valves 123 correspond one-to-one with the gas inlets 122 and each pulse valve 123 is located at the end of each gas inlet 122 connected to the gas chamber 121, that is, the front end of the pulse valve 123 is connected to the gas chamber 121, and the rear end of the pulse valve 123 is directly connected to the gas inlet 122. Preferably, the gas chamber 121 can be directly connected to the front end of the pulse valve 123, but is not limited thereto, and other components can also be provided between the gas chamber 121 and the front end of the pulse valve 123.

In some embodiments, one gas chamber 121 is connected to one gas inlet 122, as shown in FIG. 3, but it is not limited thereto. One gas chamber 121 can also be connected to a plurality of gas inlets 122, as shown in FIG. 4, and the number of gas inlets 122 connected to each gas chamber 121 can be the same or different, depending on the specific situation. In the gas distribution assembly 100, the plurality of gas inlets 122 are distributed in a planar manner, for example, a planar distribution. Distributing process gas to the surface of the substrate 900 includes that when the pulse valve 123 is opened, the process gas in the gas chamber 121 is delivered from the gas inlet 122 to the reaction chamber 301, that is, the gas distribution assembly 100 introduces gas into the reaction chamber 301 in a planar manner through the plurality of gas inlets 122, thereby distributing gas to the substrate 900 in a planar manner.

It should be noted that the plurality of gas inlets 122 in the gas distribution assembly 100 can be distributed in a planar manner to distribute gas to the substrate 900 in a planar manner, but is not limited thereto. The plurality of gas inlets 122 can also be distributed in a curved manner, and the specific curved distribution manner will be described in subsequent embodiments.

In the existing substrate processing device, the control valve 32 is provided on the pipeline. Before replacing the gas, the gas in the portion of the pipeline downstream of the control valve 32 and in the showerhead 31 needs to be exhausted. A large amount of gas needs to be exhausted and it is easy to leave residues, resulting in the mixing of the gases successively introduced into the reaction chamber 301 within one cycle T. After the mixed first gas and second gas chemically react in the gaseous state, the reaction products are deposited on the surface of the substrate, reducing the film uniformity of the atomic layer deposition.

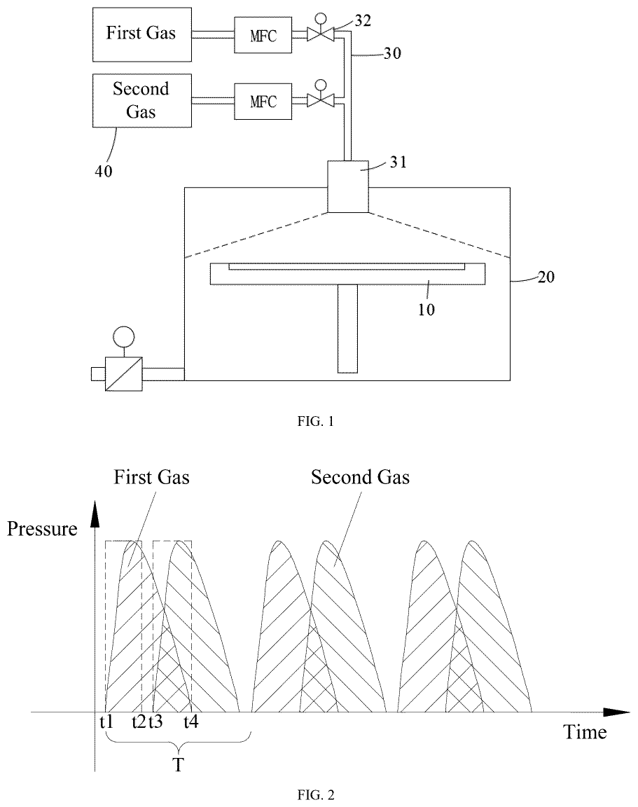

In this embodiment, when the pulse valve 123 is opened, the gas in the gas chamber 121 is delivered to the reaction chamber 301 through the gas inlet 122, realizing the distribution of gas to the surface of the substrate 900 by the gas distribution assembly 100. When the pulse valve 123 is closed, the gas at the front end of the pulse valve 123, including but not limited to the gas in the gas chamber 121, cannot enter the reaction chamber 301, and since the rear end of the pulse valve 123 is directly connected to the gas inlet 122, only the gas inlet 122 is at the rear end of the pulse valve 123. Referring to FIGS. 1 to 5, the volume of the gas inlet 122 is much smaller relative to the interior of the entire gas distribution assembly 100 and the pipeline. Moreover, during the operation of the substrate processing device, the reaction chamber 301 is continuously evacuated under negative pressure. By reducing the volume outside the reaction chamber 301, both the exhaust volume and exhaust difficulty are minimized, thereby minimizing residual gases in the reaction chamber 301 and reducing mixing gases that are introduced into the reaction chamber 301 during successive openings of the pulse valve 123, thereby improving film formation quality and product yield.

In some embodiments, the switching frequency of the pulse valve 123 is greater than or equal to 100 Hz, that is, the switching cycle is less than or equal to 10 milliseconds. Optionally, the switching frequency is less than or equal to 10 kHz. For example, the switching cycle of the pulse valve 123 is 10 milliseconds, 1 millisecond, 10 microseconds, etc. The switching cycle of the pulse valve 123 is less than or equal to 10 milliseconds, that is, the pulse valve 123 can achieve high-frequency switching.

The gas distribution assembly 100 can be configured such that each time the pulse valve 123 is opened, gas is uniformly distributed to the surface of the substrate 900 through the plurality of gas inlets 122. However, due to the exhaust device 500 in communication with the reaction chamber 301 being always opened, the temperature distribution of the substrate 900, and the reaction consumption, etc., within one switching cycle, the gas concentration distribution in the reaction chamber 301 will decrease in uniformity as the switching cycle is prolonged. Therefore, the pulse valve 123 can achieve high-frequency switching, and the gas in the reaction chamber 301 can be exhausted and refreshed in a very short time, avoiding the uniform decrease of the gas concentration distribution in the reaction chamber 301 due to the prolonged switching cycle, and the overall uniformity of the process gas distribution in the reaction chamber 301 can be improved, thereby making the uniform processing of the substrate 900.

In addition, when two or more gases are alternately introduced into the gas distribution assembly 100, the pulse valve 123 can achieve high-frequency switching, which can improve the processing efficiency of the substrate 900. Exemplarily, when the process implemented by the substrate processing device is ALD, the high-frequency switching of the pulse valve 123 of the gas distribution assembly 100 to alternately provide two different process gases to the substrate 900 can improve the deposition efficiency of ALD.

Optionally, the switching frequency of the pulse valve 123 can be adjusted. Thus, the switching frequency of the pulse valve 123 can be specifically set according to the process conditions of the specific substrate 900.

In some embodiments, the pulse valve 123 includes a diaphragm layer 1231 and an actuator 1232, and the diaphragm layer 1231 can be deformed or displaced under the action of the actuator 1232 to achieve the opening or closing of the pulse valve 123. That is, the pulse valve 123 includes a diaphragm valve, and the diaphragm valve can achieve switching at the millisecond or even microsecond level (for example, the switching cycle is 10 microseconds to 10 milliseconds), improving the processing uniformity of the substrate 900 and the deposition efficiency.

The diaphragm layer 1231 can be deformed or displaced under the action of the actuator 1232. For example, the actuator 1232 and the diaphragm layer 1231 are formed integrally, and the vibration of the actuator 1232 makes the deformation or displacement of the diaphragm layer 1231, or the actuator 1232 and the diaphragm layer 1231 are formed separately, and the vibration of the actuator 1232 impacts or presses the diaphragm layer 1231 to make the diaphragm layer 1231 deform, but is not limited thereto, as long as the actuator 1232 can cause the diaphragm layer 1231 to alternately open or close the end of the gas inlet 122 connected to the gas chamber 121. Optionally, the diaphragm layer 1231 can be a metal film, such as stainless steel, etc., and the actuator 1232 is, for example, a piezoelectric element actuator or an electromagnetic actuator, but is not limited thereto, as long as the diaphragm layer 1231 can be deformed and the actuator 1232 can be controlled to drive the diaphragm layer 1231 to act at a high frequency.

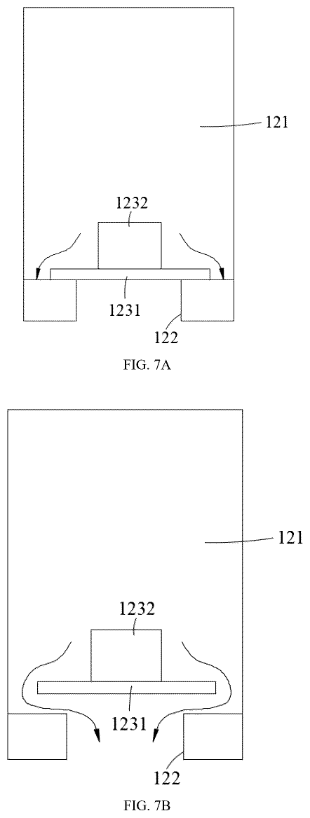

The pulse valves 123 correspond one-to-one with the gas inlets 122 and are located at the ends of the gas inlets 122 connected to the gas chamber 121. The opening of the pulse valve 123 includes that the diaphragm layer 1231 moves away from the end of the gas inlet 122 connected to the gas chamber 121, so that the gas chamber 121 communicates with the gas inlet 122. The closing of the pulse valve 123 includes that the diaphragm layer 1231 seals the end of the gas inlet 122 connected to the gas chamber 121. Exemplarily, as shown in FIG. 7A, when the pulse valve 123 is closed, the diaphragm layer 1231 covers and seals the end of the gas inlet 122 connected to the gas chamber 121, and the gas in the gas chamber 121 cannot enter the reaction chamber 301 through the gas inlet 122. As shown in FIG. 7B, when the pulse valve 123 is opened, the diaphragm layer 1231 at least moves away from the end of the gas inlet 122 connected to the gas chamber 121, so that the gas chamber 121 communicates with the gas inlet 122, and the gas in the gas chamber 121 is introduced into the reaction chamber 301 through the gas inlet 122, and the gas flow path is as indicated by the arrow in the figures.

It should be noted that the pulse valve 123 may include a diaphragm valve, but is not limited thereto. The pulse valve 123 may also include other electrically controlled valves, as long as it can achieve high-speed switching at the millisecond or even microsecond level.

In some embodiments, the depth of the gas inlet 122 is less than 5 mm. Preferably, the depth of the gas inlet 122 is less than 3 mm. Preferably, the depth of the gas inlet 122 is less than 1 mm. It can be understood that the smaller the volume of the gas inlet 122, the smaller the volume outside the reaction chamber 301. The amount of gas to be exhausted between two consecutive gas introductions into the reaction chamber 301 is smaller, the difficulty of exhausting gas is lower, the time for exhausting gas is shorter, the residual gas in the reaction chamber 301 is less, and the mixing of the gases introduced into the reaction chamber 301 when the pulse valve 123 is opened twice successively is less. Thus, since the depth of the gas inlet 122 is set to be less than 5 mm, for example, the depth of the gas inlet 122 is 1-5 mm, or the depth of the gas inlet 122 is 1-3 mm, the film formation quality can be improved.

In some embodiments, the output module 120 further includes a pressure control unit 124, and the pressure control unit 124 is used to control the gas pressure in the gas chamber 121. It can be understood that before the pulse valve 123 is opened, the reaction chamber 301 is in a stable negative pressure state. After the pulse valve 123 is opened, the amount of gas input into the reaction chamber 301 through the gas inlet 122 is related to the pressure difference between the gas chamber 121 and the reaction chamber 301. The pulse valve 123 is intermittently opened or closed, and the gas in the gas chamber 121 is input into the reaction chamber 301 through the gas inlet 122. Since the gas pressure in the gas chamber 121 can be adjusted through the pressure control unit 124, the fluctuation of the gas pressure in the gas chamber 121 can be reduced, so that the gas intake amount of the gas inlet 122 is stable. Thus, since the gas pressure in the gas chamber 121 can be controlled, the gas intake of multiple gas inlets 122 in the gas distribution assembly 100 is uniform, which is beneficial for uniformly and stably distributing gas to the surface of the substrate 900.

As shown in FIG. 3, the gas distribution assembly 100 further includes an input module 110 for connecting to the gas source device 400. The pressure control unit 124 includes a pressure sensor 1241 and a flow controller 1242. The flow controller 1242 is provided between the input module 110 and the gas chamber 121, and the pressure sensor 1241 is used to detect the gas pressure in the gas chamber 121 and output a pressure signal. The flow controller 1242 is configured to adjust the gas flow rate delivered from the input module 110 to the gas chamber 121 in response to the pressure signal.

The pressure sensor 1241 can be provided on the gas chamber 121, but is not limited thereto, as long as it can detect the gas pressure in the gas chamber 121 and output a pressure signal. In the embodiment shown in FIG. 3, the pressure control unit 124 further includes a feedback circuit for transmitting the pressure signal to the flow controller 1242, but is not limited thereto. The pressure signal can also be transmitted by, for example, wireless communication, as long as it can be transmitted to the flow controller 1242. The flow controller 1242 includes, for example, a valve with an adjustable opening degree provided on the pipeline that connects the gas chamber 121 with the input module 110, but is not limited thereto, as long as it can adjust the gas flow rate delivered from the input module 110 to the gas chamber 121 in response to the pressure signal.

The flow controller 1242 controls the flow rate between the input module 110 and the gas chamber 121 in real time according to the gas pressure in the gas chamber 121, that is, when the gas pressure value corresponding to the pressure signal is lower than the preset threshold, the gas intake flow rate is increased, and when the gas pressure value corresponding to the pressure signal is higher than the preset threshold, the gas intake flow rate is decreased, so as to control the gas pressure in the gas chamber 121 and make it stable, and further improve the reaction uniformity in the reaction chamber 301.

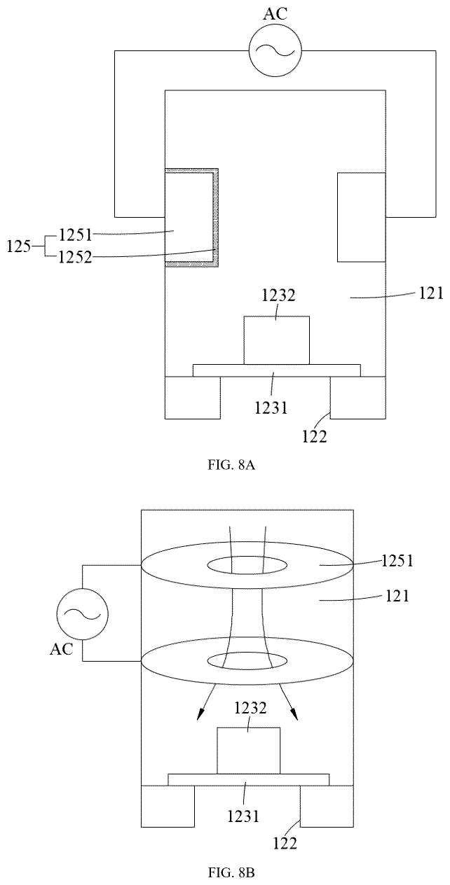

As shown in FIGS. 3, 8A and 8B, each of at least a part of the output modules 120 further includes a plasma generator 125, and the plasma generator 125 is provided in the gas chamber 121. By setting the plasma generator 125 in the gas chamber 121, the plasma generator 125 can ionize the gas raw materials. The input module 110 does not need to be connected to the plasma source, and the output module 120 can provide plasma, which can reduce the cost and volume of the substrate processing device, or the input module 110 is connected to the plasma source, that is, the gas source device 400 is the plasma source, and the gas raw materials can be ionized again in the gas chamber 121 and then input into the reaction chamber 301 through the gas inlet 122 and distributed to the surface of the substrate 900.

As shown in FIGS. 8A and 8B, the plasma generator 125 includes two working electrodes that are opposite to each other and spaced apart. Each of the two working electrodes includes a discharge electrode 1251, and at least one working electrode further includes a dielectric film 1252, and the dielectric film 1252 is provided on the side opposite to the discharge electrode 1251. That is, the plasma generator 125 is a Dielectric Barrier Discharge (DBD) plasma generator 125.

Optionally, the dielectric film 1252 is formed on the entire outer surface of the discharge electrode 1251.

The two discharge electrodes 1251 can be connected to a high-frequency voltage source. The two working electrodes are configured such that at least a part of the gas in the gas chamber 121 can pass between the two working electrodes. Exemplarily, the two working electrodes are both provided on the side wall of the gas chamber 121, and the gas can pass through the space between the two working electrodes and then be ionized, and then be introduced into the reaction chamber 301 through the gas inlet 122 when the pulse valve 123 is opened, as shown in FIG. 8A, or the two working electrodes are successively provided on the gas flow path in the gas chamber 121, and each of the two working electrodes includes a hollow portion, for example, the two working electrodes are formed in a ring shape or a mesh shape, etc. The gas can pass through the hollow portion of one working electrode, enter the space between the two working electrodes and then be ionized, and pass through the hollow portion of the other working electrode, and then be introduced into the reaction chamber 301 through the gas inlet 122 when the pulse valve 123 is opened, as shown in FIG. 8B, but it is not limited thereto, as long as the gas can pass between the two electrodes.

It should be noted that the plasma generator 125 can be a dielectric barrier discharge plasma generator 125, and the two working electrodes are connected to a high-frequency power source, but is not limited thereto. Other types of plasma generators 125 can also be provided in the output module 120, as long as it can ionize the gas to generate plasma.

In addition, it should be noted that the gas chamber 121 of the gas distribution assembly 100 is provided with the plasma generator 125, and whether the substrate processing device including the gas distribution assembly 100 further includes other plasma generators 125 is not specifically limited in the present application.

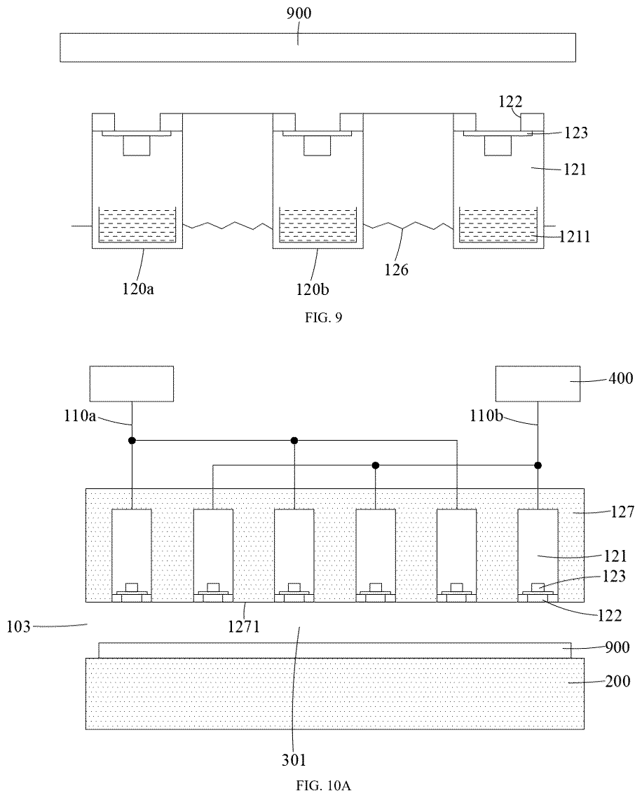

In the embodiment shown in FIG. 9, each of at least a part of the gas chambers 121 includes an evaporation cavity 1211, and the evaporation cavity 1211 is used to accommodate a solid or liquid evaporation source, and the evaporation cavity 1211 has an opening facing the pulse valve 123. Thus, the gas distribution assembly 100 can be used to deposit a thin film on the substrate 900 by evaporation.

In some embodiments, the gas chamber 121 of each of multiple output modules 120 includes an evaporation cavity 1211, and in at least two output modules 120 with the evaporation cavity 1211, the pulse valves 123 can be independently switched on and off. For example, the multiple output modules 120 include a first output module 120a and a second output module 120b, and the pulse valves 123 in the first output module 120a and the second output module 120b can be independently switched on and off. Thus, the evaporation cavities 1211 of the first output module 120a and the second output module 120b can accommodate different evaporation sources, and a composite thin film can be deposited on the substrate 900. It can be understood that the composite thin film can be a thin film formed by alternately stacking two materials, but is not limited thereto. The multiple output modules 120 can include the first to the Nth output modules, any adjacent two of which the pulse valves 123 can be independently switched on and off. The gas distribution assembly 100 can be used to deposit a composite thin film formed by alternately stacking N materials on the substrate 900, where N is less than 3.

Optionally, the gas distribution assembly 100 further includes a temperature controller 126, and the temperature controller 126 is used to control the temperature of the evaporation source accommodated in the evaporation cavity 1211, so that the evaporation source undergoes a physical reaction and/or a chemical reaction to generate gas, and the gas is input into the reaction chamber 301 through the gas inlet 122 when the pulse valve 123 is opened.

Due to preparing gas in the gas chamber 121, the gas distribution assembly 100 has a simpler structure compared with the solution of directly introducing gas through the input module 110. In addition, directly preparing gas in the gas chamber 121 is suitable for providing chemically unstable gases and gases that are not easy to store. In some embodiments, the gas chamber 121 includes an evaporation cavity 1211, and a plasma generator 125 is provided in the gas chamber 121. Thus, the gas distribution assembly 100 can be used for a plasma-assisted evaporation deposition process.

In an embodiment provided in the present application, the gas distribution assembly 100 includes multiple input modules 110, and the input module 110 is used to connect to the gas source device 400. Each input module 110 is connected to at least one output module 120, one output module 120 is connected to one input module 110. In at least two of the multiple input modules 110, the pulse valves 123 of the output modules 120 connected thereto can be independently switched on and off. Thus, by controlling the pulse valves 123 of the output modules 120 connected to the at least two input modules 110 to be alternately switched on and off, the gas distribution assembly 100 can alternately introduce different gases into the reaction chamber 301.

In one embodiment, the gas distribution assembly 100 includes multiple input modules 110, and the pulse valves 123 of the output modules 120 connected to each input module 110 can be independently switched on and off, or the multiple input modules 110 can be divided into multiple groups, each group can include one or more input modules 110, and the pulse valves 123 of the output modules 120 connected to each group of input modules 110 can be independently switched on and off, but it is not limited thereto, as long as the pulse valves 123 of the output modules 120 connected to at least two input modules 110 can be independently switched on and off.

Exemplarily, as shown in FIGS. 3 and 5, the gas distribution assembly 100 includes two input modules 110, namely a first input module 110a and a second input module 110b. The gas source device 400 connected to the first input module 110a provides a first gas, and the gas source device 400 connected to the second input module 110b provides a second gas. Within one cycle period T, the pulse valve 123 of the output module 120 connected to the first input module 110a is controlled to be opened at time t1 and closed at time t2. The pulse valve 123 of the output module 120 connected to the second input module 110b is controlled to be opened at time t3 and closed at time t4, so that the gas distribution assembly 100 can alternately introduce the first gas and the second gas into the reaction chamber 301.

Since the gas distribution assembly 100 provided in the embodiment of the present application is adopted, the volume at the rear end of the pulse valve 123 is significantly reduced, the amount of exhaust gas is reduced, and the difficulty of exhaust is decreased. Thus, the residual gas in the reaction chamber 301 is reduced, the mixing of the gases introduced into the reaction chamber 301 when the pulse valve 123 is opened twice successively is reduced, the mixing rate of the first gas and the second gas is reduced, as shown in FIG. 6, and the pulse valve 123 can achieve high-frequency switching, avoiding the decrease in the uniformity of the gas concentration distribution in the reaction chamber 301 due to the prolonged switching cycle, improving the overall uniformity of the process gas distribution in the reaction chamber 301, and further improving the film formation quality and product yield.

Exemplarily, the substrate processing device includes the gas distribution assembly 100, and the substrate processing device is used for performing atomic layer deposition on the substrate 900. For example, when depositing a titanium nitride (TiN) film layer by atomic layer deposition, the first gas is titanium chloride (TiCl₄), and the second gas is ammonia (NH₃). The output module 120 connected to the first input module 110a and the output module 120 connected to the second input module 110b alternately input TiCl₄ and NH₃ into the reaction chamber 301, so that a TiN film layer can be deposited on the surface of the substrate 900 by the atomic layer deposition, and the thickness uniformity of the film layer is improved, and the deposition efficiency is improved.

Exemplarily, a plasma generator 125 is provided in the gas chamber 121 of the output module 120 for introducing the second gas, and the plasma generator 125 can ionize at least a part of the second gas to generate plasma, realizing plasma-assisted atomic layer deposition and further improving the efficiency of atomic layer deposition.

It should be noted that the substrate processing device includes the gas distribution assembly 100, and the substrate processing device is used for performing atomic layer deposition on the substrate 900. The film layer deposited by the atomic layer deposition is not limited to TiN, and the specific film layer can be determined according to the situation. The plasma generator 125 can be provided in any gas chamber 121 connected to any input module 110 among the multiple input modules 110 to realize plasma-assisted atomic layer deposition and further improve the efficiency of atomic layer deposition. For example, the plasma generator 125 is provided in each gas chamber 121, or the plasma generator 125 is provided in all the gas chambers 121 connected to a part of the input modules 110 among the multiple input modules 110, or the plasma generator 125 is provided in a part of the gas chambers 121 connected to one input module 110, which can be determined according to the situation. It should be understood that the above embodiments are only for exemplary illustration, and there can be other setting manners for the plasma generator 125, and specific embodiments will not be exhaustively listed.

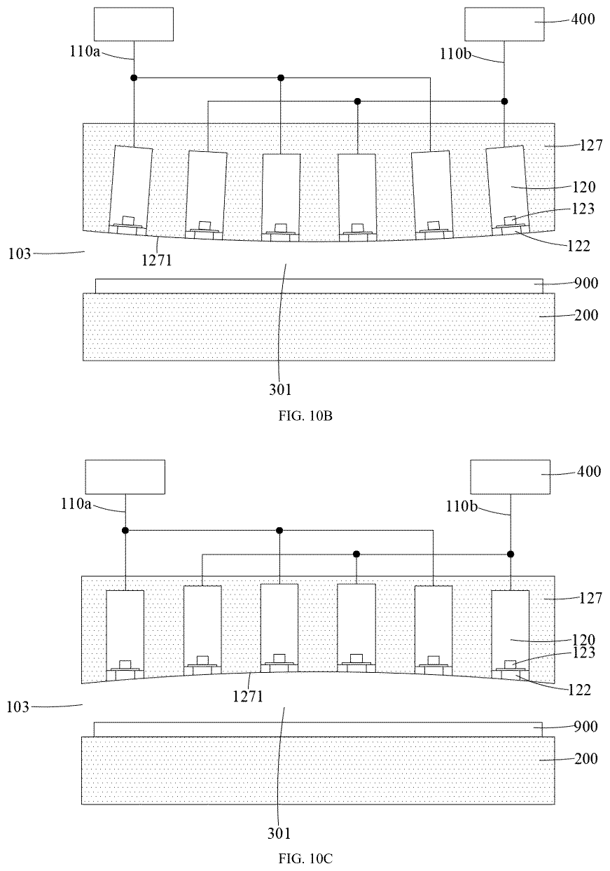

Referring to the embodiments shown in FIGS. 10A-10C, the gas distribution assembly 100 includes a showerhead 127, and the gas inlets 122 are located in the showerhead 127. It can be understood that the end surface 1271 of the showerhead 127 can be a plane, and the gas inlets 122 are located in the showerhead 127. For example, the gas inlets 122 are through holes in the showerhead 127, and the diaphragm layer 1231 covers one end of the through hole connected to the gas chamber 121, and the ends of the through holes are located on the end surface 1271 of the showerhead 127.

In one embodiment, the ends of all the gas inlets 122 are uniformly distributed on the end surface 1271 of the showerhead 127, for example, in an array distribution or a circular arrangement, etc. In one embodiment, all the gas inlets 122 have the same size, but it is not limited thereto. The sizes of the gas inlets 122 can be partially the same or all different, and the distribution of the gas inlets 122 can be non-uniform, which can be set based on the process executed by the substrate processing device.

In some embodiments, the multiple input modules 110 include a first input module 110a and a second input module 110b. Both the first input module 110a and the second input module 110b are used to connect to the gas source device 400. The first input module 110a and the second input module 110b are respectively connected to at least one output module 120, and each output module 120 is connected to one of the first input module 110a and the second input module 110b. In the first input module 110a and the second input module 110b, the pulse valves 123 of the output modules 120 connected thereto can be independently switched on and off. For the output module 120 connected to the first input module 110a, the ends of its gas inlets 122 are uniformly distributed on the end surface 1271 of the showerhead 127. For the output module 120 connected to the second input module 110b, the ends of its gas inlets 122 are uniformly distributed on the end surface 1271 of the showerhead 127. Thus, the gas distribution assembly 100 can be used to alternately introduce two gases into the reaction chamber 301 uniformly, but it is not limited thereto. There can be more than two input modules 110, and the ends of the gas inlets 122 of the output modules 120 connected to each input module 110 are uniformly distributed on the end surface 1271 of the showerhead 127, depending on the specific situation.

Referring to FIGS. 10A-10C, the gas distribution assembly 100 is applied to the substrate processing device, and the substrate processing device includes the gas distribution assembly 100 and a substrate seat 200 for supporting the substrate 900. Optionally, the substrate seat 200 can move to approach or move away from the gas distribution assembly 100. The reaction chamber 301 includes the space between the substrate seat 200 and the end surface 1271. Generally, the reaction chamber 301 is communicated with the exhaust device 500 (as shown in FIG. 5), and the exhaust device 500 provides a negative pressure to exhaust the gas in the reaction chamber 301. The arrow in the FIG. 5 indicates the gas flow direction when the exhaust device 500 exhausts the gas in the reaction chamber 301, and the gas exhausted by the exhaust device 500 includes the gas in the reaction chamber 301 and the gas in the gas inlet 122.

Exemplarily, the end surface 1271 is a plane, a convex surface or a concave surface, as shown in FIGS. 10A, 10B and 10C respectively, and the ends of the gas inlets 122 are located on the end surface 1271, so that the ends of the gas inlets 122 are distributed on a plane or a curved surface.

It can be understood that when the ends of the gas inlets 122 are distributed on a convex surface or a concave surface, the extending directions of the multiple gas inlets 122 are parallel to each other. Optionally, the extending directions of the multiple parallel gas inlets 122 are perpendicular to the surface of the substrate 900 supported by the substrate seat 200 when the gas distribution assembly 100 is applied to the substrate processing device, as shown in FIGS. 10A and 10C. In some embodiments, the extending directions of the multiple gas inlets 122 are perpendicular to the tangent plane of the end surface 1271 at its intersection point with the end surface 1271, as shown in FIG. 10B, but it is not limited thereto. In some embodiments, the extending directions of the gas inlets 122 can be specifically set according to the process executed by the substrate processing device.

Exemplarily, the reaction chamber 301 being communicated with the exhaust device 500 includes a circumferential gap 103 is formed between the showerhead 127 and the outer edge of the substrate seat 200, and the exhaust device 500 is communicated with the reaction chamber 301 through the gap 103, and the exhaust device 500 can exhaust the gas in the reaction chamber 301 from the gap 103. In some embodiments, the substrate processing device further includes a cavity accommodating the reaction chamber 301, and the exhaust device 500 is connected to the cavity and is communicated with the reaction chamber 301 through the gap 103.

In the embodiment shown in FIG. 10A, the end surface 1271 of the showerhead 127 is a plane, featuring a simple structure. In the embodiment shown in FIG. 10B, the end surface 1271 of the showerhead 127 is set as a convex surface, which can increase the width of the gap 103 without increasing the volume of the reaction chamber 301, thereby reducing the amount of exhaust gas and improving the exhaust efficiency, and further reducing the mixing degree of the gases introduced into the reaction chamber 301 twice successively. In the embodiment shown in FIG. 10C, the end surface 1271 of the showerhead 127 is a concave surface, which can increase the residence time of the gas in the reaction chamber 301 and improve the gas utilization rate. In addition, it can be understood that when exhausting the gas in the reaction chamber 301, the narrower the gap 103 is, the lower the exhaust efficiency of the exhaust device 500 will be.

It should be noted that when the end surface 1271 of the showerhead 127 is a convex surface or a concave surface, there is no specific limitation on whether the convex surface and the concave surface are regular, as long as they are generally convex or concave.

Referring to the embodiments shown in FIGS. 3, 11 and 12, the gas distribution assembly 100 includes multiple input modules 110. The multiple input modules 110 include a first input module 110a and a second input module 110b. In the first input module 110a and the second input module 110b, the pulse valves 123 of the output modules 120 connected thereto can be independently switched on and off. In the output module 120 connected to the first input module 110a, the gas inlets 122 are distributed in the first strip-shaped region 101, and in the output module 120 connected to the second input module 110b, the gas inlets 122 are distributed in the second strip-shaped region 102. The first strip-shaped region 101 and the second strip-shaped region 102 are alternately arranged in a plane along a circular line, and the first strip-shaped region 101 and the second strip-shaped region 102 extend radially along the circular line, and the circular line can pass through the cross-section A-A in FIG. 11. It can be understood that the first strip-shaped region 101 and the second strip-shaped region 102 extend radially along the circular line, including approximately extending radially along the circular line.

Exemplarily, referring to FIG. 11, the first strip-shaped region 101 and the second strip-shaped region 102 are rectangular, but it is not limited thereto. In some embodiments, the first strip-shaped region 101 and the second strip-shaped region 102 can be fan-shaped, or the edges of the first strip-shaped region 101 and the second strip-shaped region 102 extending radially along the circular line can be curved, and the shapes and sizes of the first strip-shaped region 101 and the second strip-shaped region 102 can be the same or different, depending on the specific situation. The extending directions of the first strip-shaped region 101 and the second strip-shaped region 102 can also not be along the radial direction of the circular line, and their extending directions can be the same or different.

Optionally, the widths of the first strip-shaped region 101 and the second strip-shaped region 102 on the circular line are smaller than the substrate 900. Optionally, the distribution range of the gas inlets 122 in the first strip-shaped region 101 and the second strip-shaped region 102 has a length greater than that of the substrate 900 along the radial direction of the circular line.

Optionally, in the output module 120 connected to the first input module 110a, the gas inlets 122 are arranged in the first strip-shaped region 101, for example, radially along the circular line, in a single row and at equal intervals, or in a matrix arrangement. In the output module 120 connected to the second input module 110b, the gas inlets 122 are arranged radially along the circular line, in a single row and at equal intervals, or in a matrix arrangement in the second strip-shaped region 102. Optionally, the arrangement of the gas inlets 122 in the first strip-shaped region 101 and the arrangement of the gas inlets 122 in the second strip-shaped region 102 can be the same or different. Optionally, the arrangement of the gas inlets 122 in the first strip-shaped region 101 and the arrangement of the gas inlets 122 in the second strip-shaped region 102 can be uniform or non-uniform. There is no specific limitation in the present application.

In the gas distribution assembly 100, multiple input modules 110 can also include a third input module to an Nth input module and the output modules 120 connected thereto, where N is greater than 3, and there is no specific limitation in the present application.

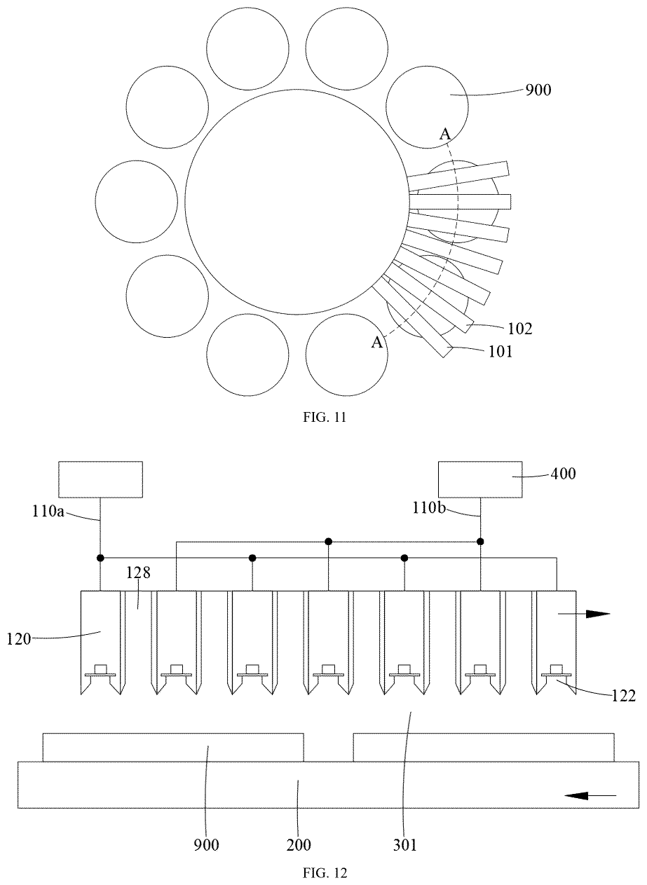

In one embodiment, referring to FIGS. 11 and 12, the gas distribution assembly 100 further includes an exhaust port 128 provided between the first strip-shaped region 101 and the second strip-shaped region 102, and the exhaust port 128 is used to connect to the exhaust device 500 to exhaust the gas in the reaction chamber 301. Optionally, an exhaust port 128 is provided between each pair of adjacent first strip-shaped regions 101 and second strip-shaped regions 102. Optionally, the exhaust port 128 is also in a strip shape or a fan shape extending radially along the circular line. Optionally, the width of the strip-shaped exhaust port 128 along the circular line is smaller than that of the substrate 900. Optionally, the length of the strip-shaped exhaust port 128 along the radial direction of the circular line is greater than that of the substrate 900.

The gas distribution assembly 100 in the embodiment shown in FIG. 11 can be applied to a substrate processing device, and the substrate processing device is a batch processing device. The substrate processing device includes a substrate seat 200, and the substrate seat 200 can support multiple substrates 900 along the circular line. In the substrate processing device, the substrate seat 200 and the gas distribution assembly 100 can rotate relatively. For example, the substrate seat 200 is configured to be rotatable, or the gas distribution assembly 100 can rotate, or both can rotate relatively or in the same direction at different speeds.

Exemplarily, when the substrate processing device operates, the gas distribution assembly 100 and the substrate seat 200 rotate relatively. The first input module 110a inputs the first gas, and the second input module 110b inputs the second gas. For a region on the substrate 900 supported by the substrate seat 200, it periodically faces the first strip-shaped region 101, the exhaust port 128, the second strip-shaped region 102, and the exhaust port 128. Thus, for this region, the first gas is distributed, the first gas is removed, the second gas is distributed, and the second gas is removed, periodically. Thus, substrate 900 processing processes such as ALD, ALE, and evaporation deposition can be performed on the surface of the substrate 900 in batches. Moreover, the volume at the rear end of the pulse valve 123 is significantly reduced, the amount of exhaust gas is reduced, the difficulty of exhaust is decreased, so that the residual gas in the reaction chamber 301 is reduced, the mixing of the gases introduced into the reaction chamber 301 when the pulse valve 123 is opened twice successively is reduced, the mixing rate of the first gas and the second gas is reduced, and the processing uniformity is improved.

Furthermore, the exhaust port 128 and the gas inlet 122 are both in a flared shape, so that when the gas distribution assembly is applied to the substrate processing device, the sizes of ends of the exhaust port 128 and the gas inlet 122 near the substrate seat 200 are larger than that of ends of the exhaust port 128 and the gas inlet 122 away from the substrate seat 200. Thus, gas guiding can be realized, the difficulty of exhausting gas from the reaction chamber 301 is reduced, and the mixing degree of the first gas and the second gas can be further reduced. Exemplarily, the exhaust port 128 and the gas inlet 122 being both in a flared shape includes that the inner walls of the exhaust port 128 and the gas inlet 122 are in a flared shape as a whole, or the first ends of the exhaust port 128 and the gas inlet 122 are in a column shape and only the inner walls of last ends of the exhaust port 128 and the gas inlet 122 are in a flared shape. Optionally, the ends of at least part of the radial inner walls of the exhaust port 128 and the gas inlet 122 are connected.

The present application further provides a substrate processing device, including a reaction chamber 301 for accommodating the substrate 900; a substrate seat 200 for supporting the substrate 900, and the gas distribution assembly 100 disclosed above for distributing gas to the surface of the substrate 900.

The substrate processing device can be used for evaporation deposition, atomic layer deposition of thin films, or atomic layer etching, etc., but it is not limited thereto, and there is no specific limitation on the process executed by the substrate processing device in the present application.

The substrate processing device of the present application can be horizontally arranged, that is, the substrate seat 200 and the gas distribution assembly 100 are respectively horizontally arranged, and the substrate seat 200 and the gas distribution assembly 100 are arranged up and down. The substrate seat 200 is horizontally arranged, that is, the substrate seat 200 can horizontally support the substrate 900.

Optionally, the substrate processing device of the present application can be arranged obliquely or vertically, that is, the substrate seat 200 and the gas distribution assembly 100 are respectively arranged obliquely or vertically, and the gas intake surface of the gas distribution assembly 100 is arranged to face the surface of the substrate 900 supported by the substrate seat 200. The substrate seat 200 is arranged obliquely or vertically, that is, the substrate seat 200 can hold the substrate 900 obliquely or vertically. Thus, the floor area of the substrate processing device can be reduced, and the cost can be reduced.

The terms “first”, “second”, etc. are only used for descriptive purposes and should not be construed as indicating or implying relative importance or implicitly indicating the quantity of the indicated technical features. Thus, the features defined with “first”, “second”, etc. can explicitly or implicitly include one or more of such features. In the description of the present application, “multiple” means two or more, unless specifically defined otherwise.

In the present application, unless otherwise clearly defined and limited, the terms “assembly”, “connection”, etc. should be understood in a broad sense. For example, it can be a fixed connection, a detachable connection, or an integral connection; it can be a mechanical connection or an electrical connection; it can be directly connected, or indirectly connected through an intermediate medium, or it can be the internal connection between two components or the interaction relationship between two components. For those skilled in the art, the specific meanings of the above terms in the present application can be understood according to the specific situation.

In the description of this specification, the descriptions with reference to the terms “some embodiments”, “exemplarily”, etc. mean that the specific features, structures, materials, or characteristics described in combination with the embodiment or example are included in at least one embodiment or example of the present application. In this specification, the schematic representations of the above terms are not necessarily directed to the same embodiment or example. Moreover, the specific features, structures, materials, or characteristics described can be combined in a suitable manner in any one or more embodiments or examples. In addition, those skilled in the art can combine the features of different embodiments or examples and combine different embodiments or examples described in this specification without conflict.

Although the embodiments of the present application have been shown and described above, it can be understood that the above embodiments are exemplary and should not be construed as limiting the present application. Those skilled in the art can make changes, modifications, substitutions, and variations to the above embodiments within the scope of the present application. Therefore, any changes or modifications made according to the claims and the specification of the present application should fall within the scope covered by the patent of the present application.

What is claimed is:

1. A gas distribution assembly, applied for a substrate processing device, the substrate processing device comprising a substrate seat and a reaction chamber, the reaction chamber being configured to accommodate a substrate, the substrate seat being configured to support the substrate, the gas distribution assembly being configured to distribute gas to a surface of the substrate;
wherein the gas distribution assembly comprises:
at least one output module comprising a gas chamber, at least one gas inlet, and a pulse valve located between the gas chamber and the at least one gas inlet, wherein the gas chamber is connected to the at least one gas inlet, the pulse valve corresponds one-to-one with each gas inlet and is located at an end of each gas inlet connected to the gas chamber, and when the gas distribution assembly comprises a plurality of gas inlets, the plurality of gas inlets are distributed in a planar or curved manner;
wherein the gas distribution assembly is configured to distribute gas to the surface of the substrate by:
when the pulse valve is opened, delivering gas in the gas chamber to the reaction chamber via the at least one gas inlet.

2. The gas distribution assembly according to claim 1, wherein a switching frequency of the pulse valve is greater than or equal to 100 Hz.

3. The gas distribution assembly according to claim 2, wherein the switching frequency of the pulse valve is adjustable.

4. The gas distribution assembly according to claim 2, wherein the pulse valve comprises a diaphragm layer and an actuator, and the diaphragm layer is deformable or displaceable under an action of the actuator to open or close the pulse valve;
wherein opening of the pulse valve comprises the diaphragm layer moving away from the end of each gas inlet that is connected to the gas chamber, to allow the gas chamber to be in communication with each gas inlet; and closing of the pulse valve comprises the diaphragm layer sealing the end of each gas inlet that is connected to the gas chamber.

5. The gas distribution assembly according to claim 1, wherein a depth of the at least one gas inlet is less than 5 mm.

6. The gas distribution assembly according to claim 1, wherein each output module further comprises a pressure control unit configured to control gas pressure in the gas chamber.

7. The gas distribution assembly according to claim 6, further comprising an input module configured to connect to a gas source device;
wherein the pressure control unit comprises a pressure sensor and a flow controller, the flow controller is provided between the input module and the gas chamber, the pressure sensor is configured to detect the gas pressure in the gas chamber and output a pressure signal; and
the flow controller is configured to adjust a gas flow rate delivered from the input module to the gas chamber in response to the pressure signal, increasing gas intake flow rate when a pressure value corresponding to the pressure signal is lower than a preset threshold and decreasing the gas intake flow rate when the pressure value corresponding to the pressure signal is higher than the preset threshold.

8. The gas distribution assembly according to claim 1, wherein each of at least a portion of output modules further comprises a plasma generator provided within the gas chamber.

9. The gas distribution assembly according to claim 8, wherein the plasma generator comprises two working electrodes that are opposite and spaced apart, each of the two working electrodes comprises a discharge electrode, at least one of the two working electrodes further comprises a dielectric film provided on a side opposite to the discharge electrode;
the two working electrodes are configured to allow at least a portion of the gas in the gas chamber to pass through between the two working electrodes.

10. The gas distribution assembly according to claim 1, wherein each of at least a portion of gas chambers comprises an evaporation cavity configured to accommodate a solid or liquid evaporation source, and the evaporation cavity has an opening facing the pulse valve.

11. The gas distribution assembly according to claim 10, wherein each of multiple output modules comprises the evaporation cavity, and pulse valves are independently switched in at least two of the multiple output modules with the evaporation cavity.

12. The gas distribution assembly according to claim 1, wherein the gas distribution assembly comprises multiple input modules configured to connect to a gas source device;
each input module is connected to at least one output module, and each output module is connected to one input module; and
in at least two of the multiple input modules, the pulse valve of each output module connected to the at least two of the multiple input modules are independently switched.

13. The gas distribution assembly according to claim 12, wherein the gas distribution assembly comprises a showerhead, and an end of the at least one gas inlet is located on an end surface of the showerhead.

14. The gas distribution assembly according to claim 13, wherein the end surface is planar, convex, or concave, and a planar or curved distribution of the plurality of gas inlets comprises ends of the plurality of gas inlets being distributed on the end surface.

15. The gas distribution assembly according to claim 13, wherein ends of each gas inlet of each output module connected to each input module are uniformly distributed on the end surface of the showerhead.

16. The gas distribution assembly according to claim 12, wherein the multiple input modules comprise a first input module and a second input module, and in the first input module and the second input module, the pulse valve of each output module connected to the first input module and the second input module are independently switched;
in the output module connected to the first input module, the plurality of gas inlets are distributed within a first strip-shaped region, and in the output module connected to the second input module, the plurality of gas inlets are distributed within a second strip-shaped region; and
the first strip-shaped region and the second strip-shaped region are alternately arranged in a plane along a circular line, and the first strip-shaped region and the second strip-shaped region extend radially along the circular line.

17. The gas distribution assembly according to claim 16, further comprising an exhaust port provided between the first strip-shaped region and the second strip-shaped region, wherein the exhaust port is configured to connect to an exhaust device to exhaust gas from the reaction chamber, the exhaust port is strip-shaped and extends radially along the circular line.

18. The gas distribution assembly according to claim 17, wherein both the at least one gas inlet and the exhaust port are in a flared shape.

19. A substrate processing device, comprising:
a reaction chamber configured to accommodate a substrate;
a substrate seat configured to support the substrate; and
a gas distribution assembly being configured to distribute gas to a surface of the substrate;
wherein the gas distribution assembly comprises:
at least one output module comprising a gas chamber, at least one gas inlet, and a pulse valve located between the gas chamber and the at least one gas inlet, wherein the gas chamber is connected to the at least one gas inlet, the pulse valve corresponds one-to-one with each gas inlet and is located at an end of each gas inlet connected to the gas chamber, and when the gas distribution assembly comprises a plurality of gas inlets, the plurality of gas inlets are distributed in a planar or curved manner;
wherein the gas distribution assembly is configured to distribute gas to the surface of the substrate by:
when the pulse valve is opened, delivering gas in the gas chamber to the reaction chamber via the at least one gas inlet.
